(19) United States
(12) Patent Application Publication
(10) Pub. No.: US 2011/0289207 A1
(43) Pub. Date: Nov. 24, 2011

(54) METHOD AND APPARATUS FOR PROCESSING NETWORK VISUALIZATION

(75) Inventors: Shixia Liu, Beijing (CN); Lei Shi, Beijing (CN); Chen Wang, Beijing (CN); Chun Ying, Beijing (CN)

(73) Assignee: INTERNATIONAL BUSINESS MACHINES CORPORATION, Armonk, NY (US)

(21) Appl. No.: 13/074,086

(22) Filed: Mar. 29, 2011

(30) Foreign Application Priority Data
Mar. 30, 2010 (CN) 201010136979.7

(51) Int. Cl. G06F 15/16

(52) U.S. Cl. 709/224

(57) ABSTRACT

A method, system and computer program product for processing network visualization. The network visualization processing method includes: obtaining main-information-dimension-based topological data of an analytic object in a network; performing visualization processing to the main-information-dimension-based topological data of the analytic object so as to reveal change of a relationship between an analytic node and a neighboring node in the analytic object along the main information dimension. The network visualization processing method and apparatus according to the present invention can display dynamic change of the network based on main information dimension within a single view, and provide a better graphical resolution, so as to facilitate a user to perform analysis to the network and to reduce comprehension overhead of the user.

### CROSS-REFERENCE TO RELATED APPLICATION

This application claims priority under 35 U.S.C. §119 from Chinese Patent Application No. 201010136979.7 filed Mar. 30, 2010, the entire contents of which are incorporated herein by reference

### BACKGROUND OF THE INVENTION

1. Field of the Invention

The present invention relates to a computer network technology, and more particularly the present invention is related to a network visualization processing method and apparatus.

2. Description of the Related Art

Dynamic Network Visualization is an effective method for time-spatial analysis in several scenarios such as information network, cognitive/social network and communications network. Except for showing the static relationships of the network in each specific time, the dynamic network visualization also reveals the significant time-evolving patterns of both the entity and the relationship within the network. Previous solutions for dynamic network visualization generally fall into two categories. One is to “animate” the network and show the dynamic network as a movie, with elaborate network layouts balancing the stability and aesthetics of the time-evolving network graph. FIG. 1 illustrates a diagram of a dynamic network visualization method according to prior art. While this approach maximizes the presentation utility by simulating the movie effect, it can hardly work as an analytic method since the presentation loses the network context in time dimension when played to the user. Even if the network movie allows the user to pause, play back and relocate in the timeline, the cost for the analytics is still too big to sustain because the user needs to play the movies several times for a single task. Another method for dynamic network visualization is to represent the dynamic network by multiple small graphs. FIG. 2 shows another diagram of dynamic network visualization method according to prior art, wherein the network graphs of each time frame juxtaposed in the same picture for comparison, so it is more suitable for analysis. However, in this approach, the analysis is still less automated, the findings of both temporal and topological patterns are discovered by the manual comparison of the users. The visualization here only behaves as the presentation method, with less value add-on for analysis. Also, the multiple graphs restrict the network graph of each time within a small window, bringing larger comprehension overhead for the users.

Therefore, it is currently desirable for a network visualization processing solution which is more automated and easier for a user to understand.

### SUMMARY OF THE INVENTION

Accordingly, one aspect of the present invention provides a network visualization processing method. The method includes: obtaining main-information-dimension-based topological data of an analytic object within a network; performing visualization processing to the main-information-dimension-based topological data of the analytic object so as to reveal change of a relationship between an analytic node and a neighboring node in the analytic object along the main information dimension.

Another aspect of the present invention provides a network visualization processing apparatus. The apparatus can include: data obtaining module for obtaining main-information-dimension-based topological data of an analytic object within a network; and visualization processing module for performing visualization processing to the main-information-dimension-based topological data of the analytic object so as to reveal change of a relationship between an analytic node and a neighboring node in the analytic object along the main information dimension.

The network visualization processing method and apparatus according to the present invention can reveal dynamic change of a network based on main information dimension in a single view, and provide a better graphical resolution, so as to facilitate a user to perform analysis to the network and to reduce comprehension overhead of the user.

### BRIEF DESCRIPTION OF THE DRAWINGS

FIG. 1 illustrates a diagram of a dynamic network visualization method according to a prior art.

FIG. 2 illustrates a diagram of another dynamic network visualization method according to a prior art.

FIG. 3 illustrates a flow chart of a network visualization processing method according to an embodiment of the present invention.

FIG. 4 illustrates a main information dimension graphical diagram according to an embodiment of the present invention.

FIG. 5 illustrates a main information dimension graphical diagram according to another embodiment of the present invention.

FIG. 6 illustrates a main information dimension graphical diagram according to further embodiment of the present invention.

FIGS. 7(a)-7(b) illustrate diagrams of network visualization presentation according to an embodiment of the present invention.

FIG. 8 illustrates a flow chart of a network visualization processing method according to an embodiment of the present invention.

FIGS. 9(a)-9(c) illustrate diagrams of topological data extractions according to an embodiment of the present invention.

FIG. 10 illustrates a diagram of topological data combination according to an embodiment of the present invention.

FIG. 11 illustrates a diagram of an ego node set including two nodes according to an embodiment of the present invention.

FIG. 12 illustrates a diagram of an ego network of a spammer within one hour according to an embodiment of the present invention.

FIG. 13 illustrates a diagram of an ego network of a spammer of FIG. 12 in groups of minute.

FIG. 14 illustrates a diagram of an ego network of a normal user within one month according to an embodiment of the present invention.

FIG. 15 illustrates a diagram of an ego network of a normal user in FIG. 14 in groups of day.

FIG. 16 illustrates a diagram of an ego network of a normal user in FIG. 14 in groups of minute.

FIG. 17 illustrates a block diagram of a network visualization processing apparatus according to an embodiment of the present invention.

FIG. 18 illustrates a block diagram of a network visualization processing apparatus according to an embodiment of the present invention.

FIG. 19 illustrates a structural block diagram of a computer device capable of implementing the embodiments according to the present invention.

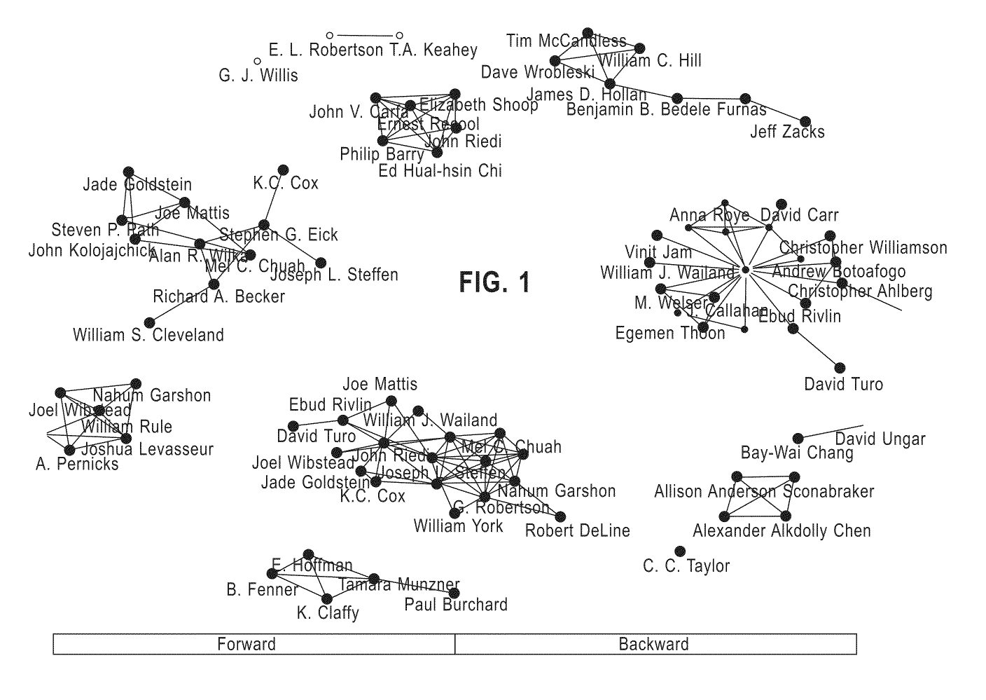

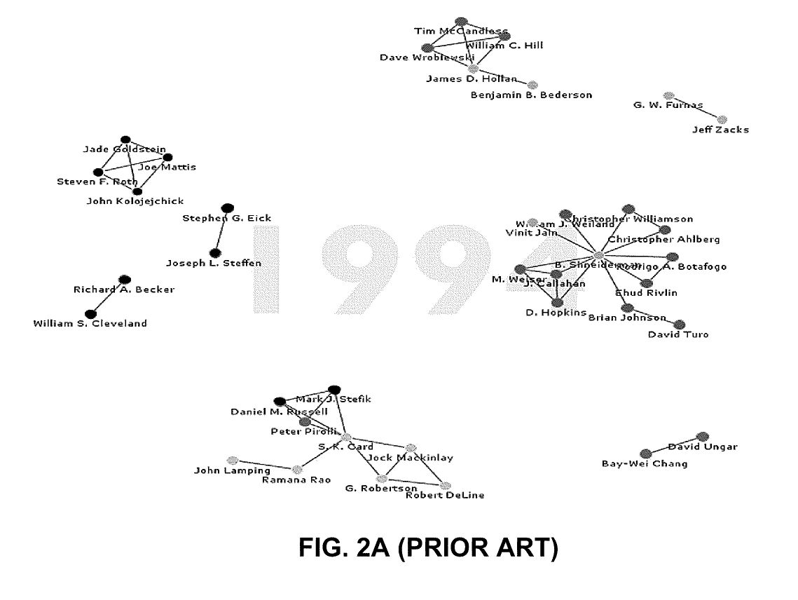

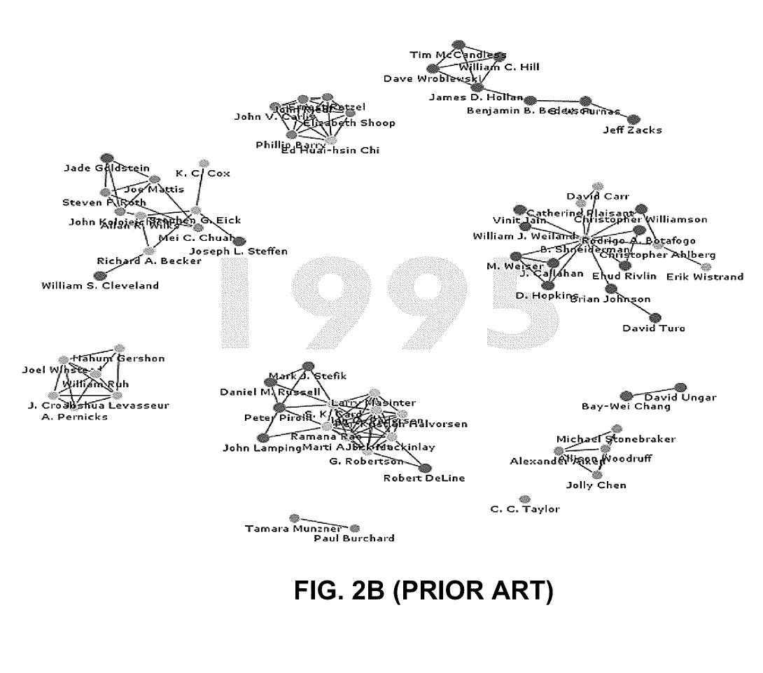

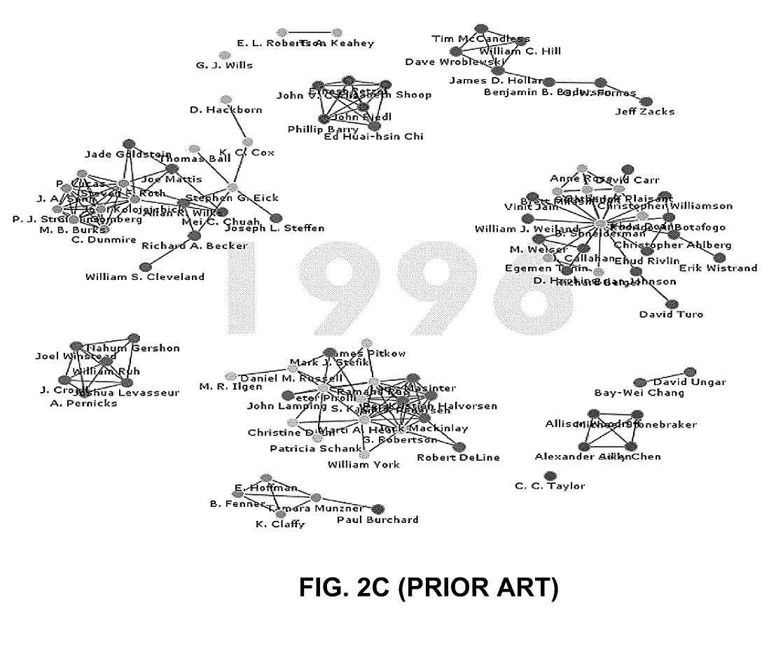

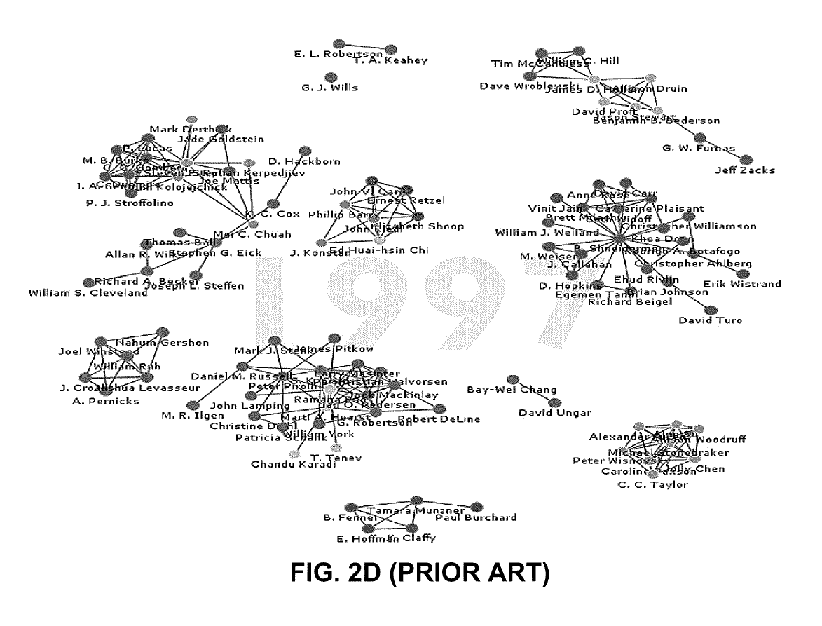

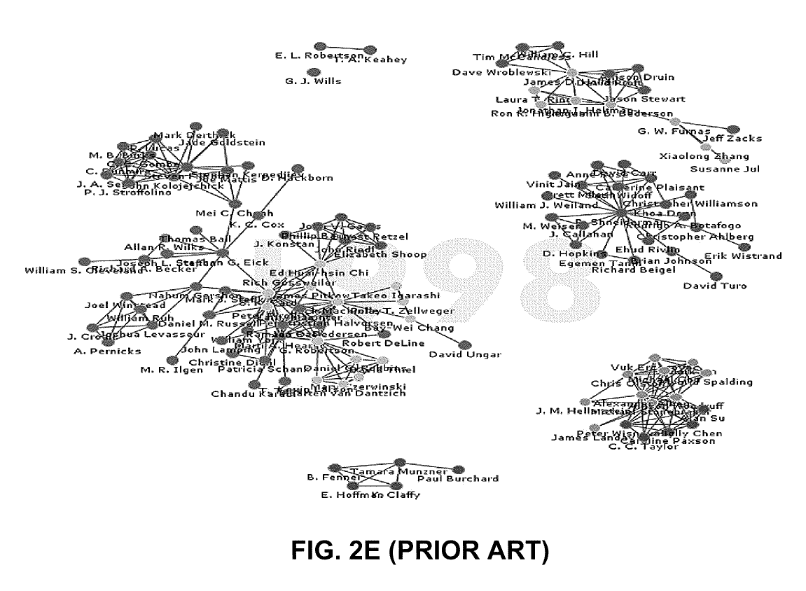

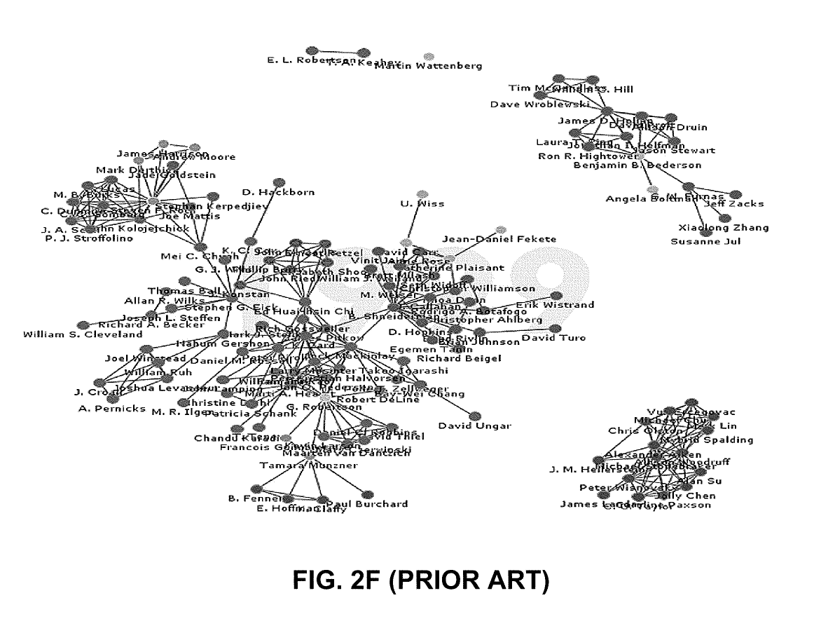

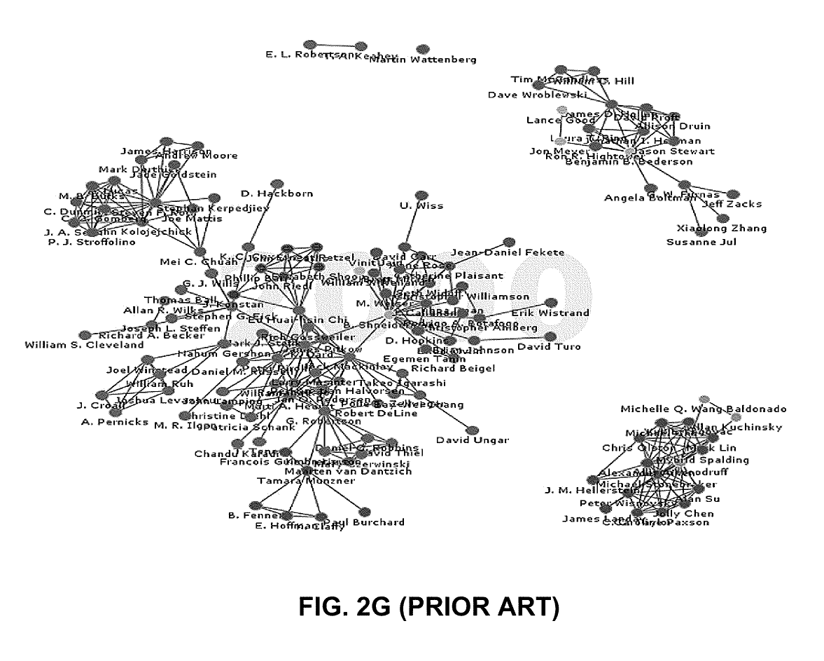

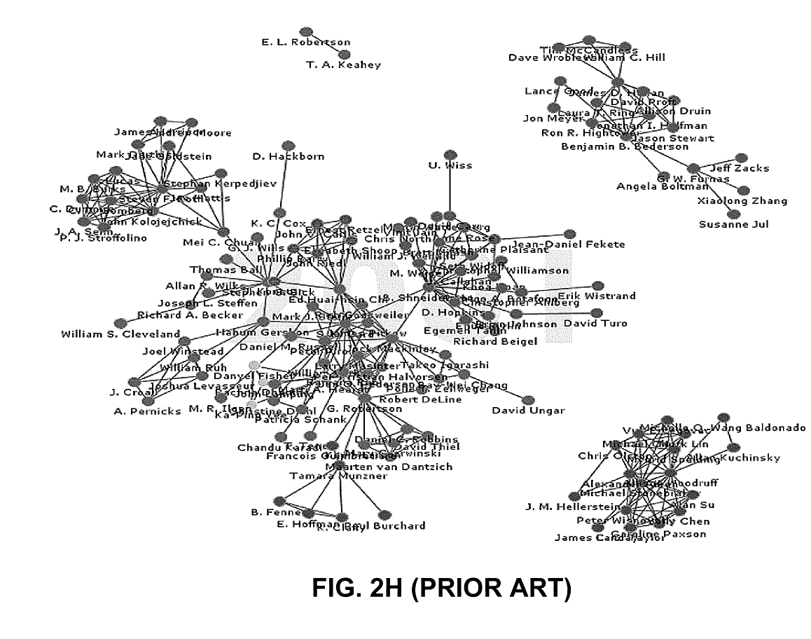

### DETAILED DESCRIPTION OF THE PREFERRED EMBODIMENTS

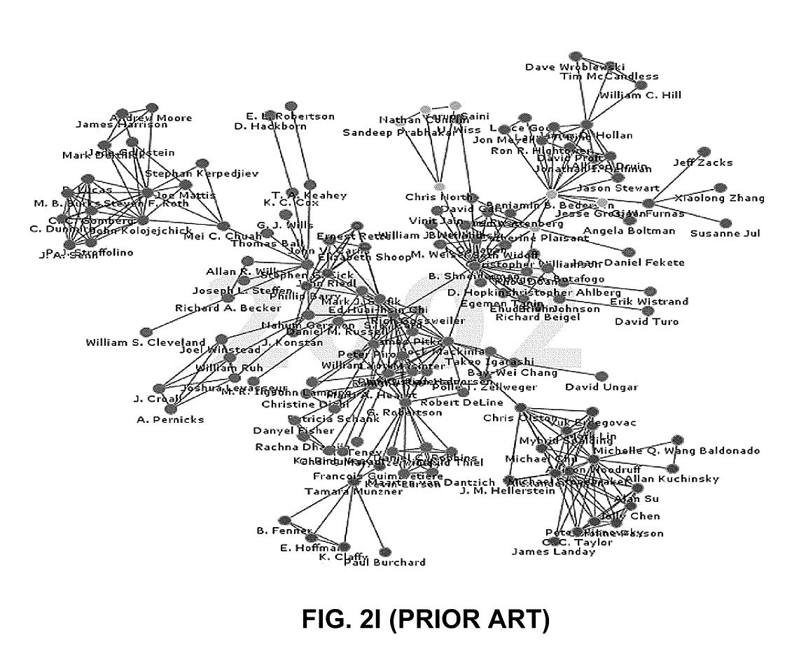

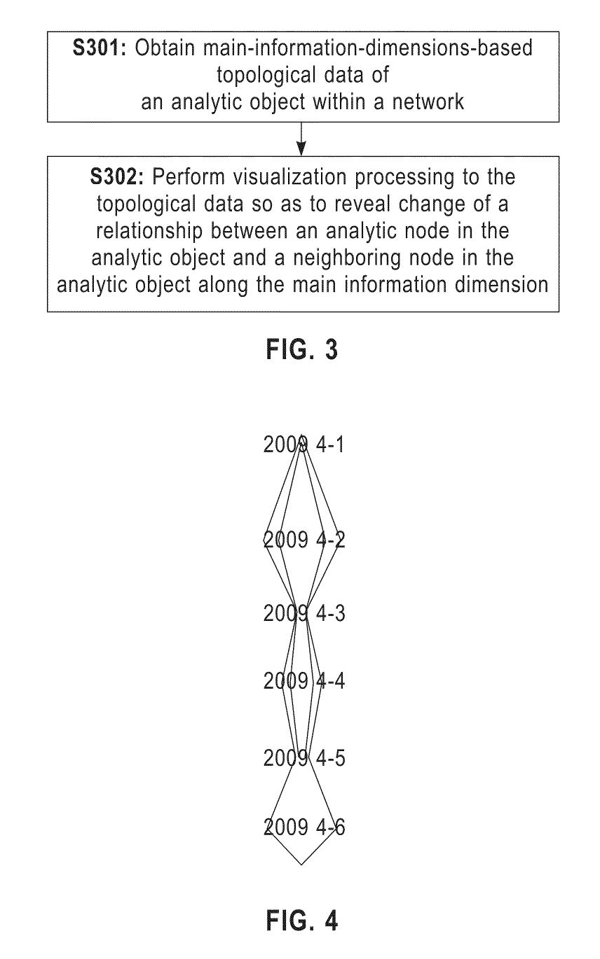

The present invention will now be described via the preferred embodiments. However, the present invention should not be viewed as being limited thereto. FIG. 3 illustrates a flow chart of a network visualization processing method according to an embodiment of the present invention. As shown in FIG. 3, the method includes the following steps:

At step S301, main-information-dimension-based topological data of an analytic object within a network are obtained. The network here can be a social network or a computer/telecommunications network. The analytic object is a network whose center is an analytic node set, wherein the analytic node set includes one or more analytic nodes. The analytic node is a node on which the user attempts to perform analysis in a specific aspect. For example, the user analyzes evolution of the node in which he/she is interested in a dimension. Main information can include time and space of various operations performed by the analytic object within the network, node within an organization, role of the node, and particular content (key words, etc) and any other information in which the user can be interested. For example, communication among a plurality of email users is a social network. When performing visualization processing on emails of one or more users in the social network as analytic nodes, for example, email sending/receiving time can be taken as main information, then the above one or more users are taken as an analytic node set, and the above one or more users and those users having email communications therewith constitute a network whose center is the analytic node set, namely, an analytic object.

With an analytic node set including one user as an example, time dimension-based topological data of a network whose center is the user can be obtained based on email communication historical record of the user. Topological data can simply include an analytic node and information such as the number or time of emails sent or received thereby. Or, topological data can include nodes and edges, wherein the nodes can include the user, i.e., analytic node, and users having email communications with the user, called neighboring nodes; the edges can represent email communications between the analytic node and neighboring nodes, and times and time information of the email communications.

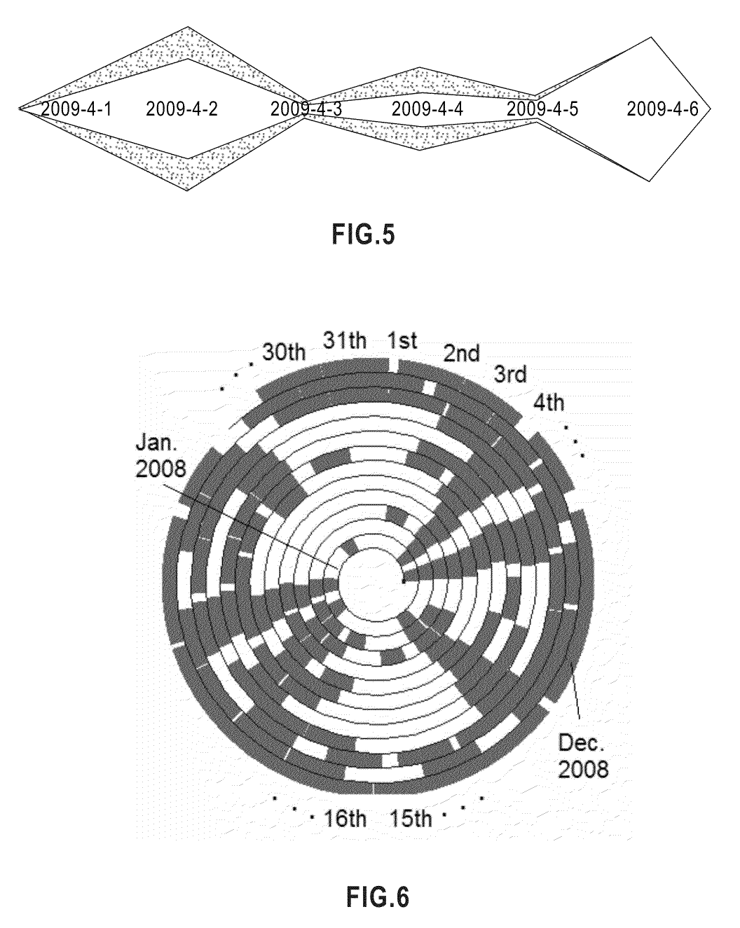

At step S302, visualization processing is performed on main-information-dimension-based topological data of the analytic object, so as to reveal change of the analytic object along the main information dimension. For example, the main information dimension can be presented as a main information dimension graph. It should be understood that the main information dimension can assume various forms. For example, the analytic node can be presented with a main information dimension aware glyph as the main information dimension graph. FIGS. 4, 5, and 6 illustrate three kinds of main information dimension graphical diagrams according to embodiments of the present invention, wherein FIG. 4 is a vertical glyph, FIG. 5 is a horizontal glyph, and FIG. 6 is a spiral glyph, wherein the main information dimension is correspondingly encoded on a vertical/horizontal/spiral axis.

As an embodiment of the present invention, in the vertical glyph as illustrated in FIG. 4, Y axis denotes a time dimension. It should be noted that it is only an example of the present invention to take time dimension as main information dimension. The main information dimension can further include location, node within an organization, role of the node, or any other information dimension in which the user is interested. In this example, a label as illustrated denotes an exact date attached to each part of the glyph. Optionally, the number of edges relevant to analytic nodes can be displayed based on graphical settings of the main information dimension graph. A thickness of each part of the glyph, for example the width of the vertical glyph of FIG. 4, denotes the total number of edges occurring on the date, wherein an internal profile denotes a total strength of source edges, and an external profile denotes a total strength of all edges. With the above email scenario as an example, the width of the vertical glyph of FIG. 4 can present the number of email communications of a user as an analytic node at a certain moment, a width of the internal profile denotes the number of emails sent by the analytic node, and the width of an external profile denotes the total number of emails sent and received by the analytic node. In FIG. 4, to make the graph intuitive and aesthetic, the width of the vertical glyph is displayed to be changed linearly between various temporal points, which, however, is only an example of the present invention. Other curve can also be employed to indicate glyph widths corresponding to respective temporal points, or it is also allowed to independently display the glyph width corresponding to each temporal point, without using curve connection.

As another embodiment of the present invention, in the horizontal glyph as illustrated in FIG. 5, X axis denotes a time dimension. It should be noted that it is only an example of the present invention to take time dimension as main information dimension. The main information dimension can further include location, node within an organization, role of the node, or any other information dimension in which the user is interested. In this example, a label as illustrated denotes an exact date attached to each part of the glyph. Optionally, the number of edges relevant to analytic nodes can be displayed based on graphical settings of the main information dimension graph. A thickness of each part of the glyph, for example the height of the horizontal glyph of FIG. 5, denotes the total number of edges occurring on the date, wherein an internal profile denotes a total strength of source edges, and an external profile denotes a total strength of all edges. With the above email scenario as an example, the height of the horizontal glyph of FIG. 5 can present the number of email communications of a user as an analytic node at a certain moment, a height of the internal profile denotes the number of emails sent by the analytic node, and the height of an external profile denotes the total number of emails sent and received by the analytic node. In FIG. 5, to make the graph intuitive and aesthetic, the height of the horizontal glyph is displayed to be changed linearly between various temporal points, which, however, is only an example of the present invention. Other curve can also be employed to indicate glyph height corresponding to respective temporal points, or it is also allowed to independently display the glyph height corresponding to each temporal point, without using curve connection.

The glyphs as illustrated in FIGS. 4 and 5 can vividly display change of communication state of the analytic node along a time dimension, such that a user subject to visualized analysis can intuitively analyze the analytic node, which avoids querying fussy historical records.

As a further embodiment of the present invention, the spiral glyph in FIG. 6 is different in that each pie in the spiral glyph denotes a particular day within one month, while each circle of the glyph denotes one month within a year. The time shape mapping can vary with data. For example, when dynamic network data only include networks for several weeks, a pie can be mapped to a day within a week, and meanwhile a circle of the glyph is mapped to a week. In FIG. 6, each block which is an overlap area between a particular pie and a circle is mapped to one day, and its color saturation degree as filled denotes a total edge strength connected to the node and occurring on the date. With the above email scenario as an example, the glyph can display periodical change of the communication state of the analytic node, for example, in which days within one month it communicates more frequently with which users. In case of querying literal email communication historical records, it is hard to watch this periodical change.

It should be noted that vertical, horizontal, and spiral time dimension aware glyphs are only examples. In implementation, the time dimension can be presented into any graph capable of displaying time information as required by analysis, for example, in a calendar manner.

Besides, neighboring nodes of the analytic node can be displayed as a neighboring node graph and connected to the above main information dimension graph, wherein a connection location between the neighboring node graph and the main information dimension graph denotes main information of an edge between the analytic node and its neighboring nodes.

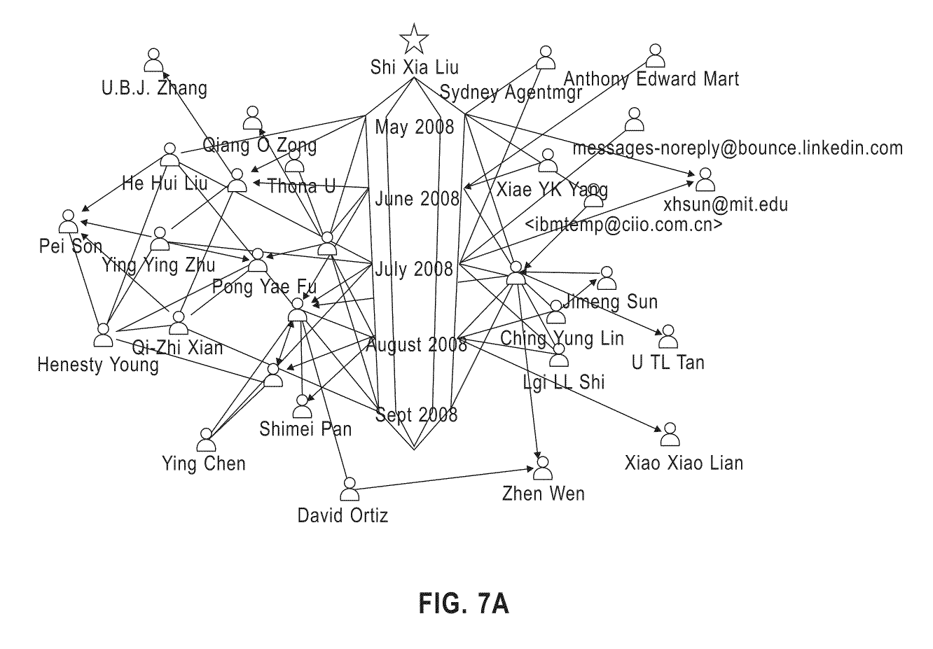

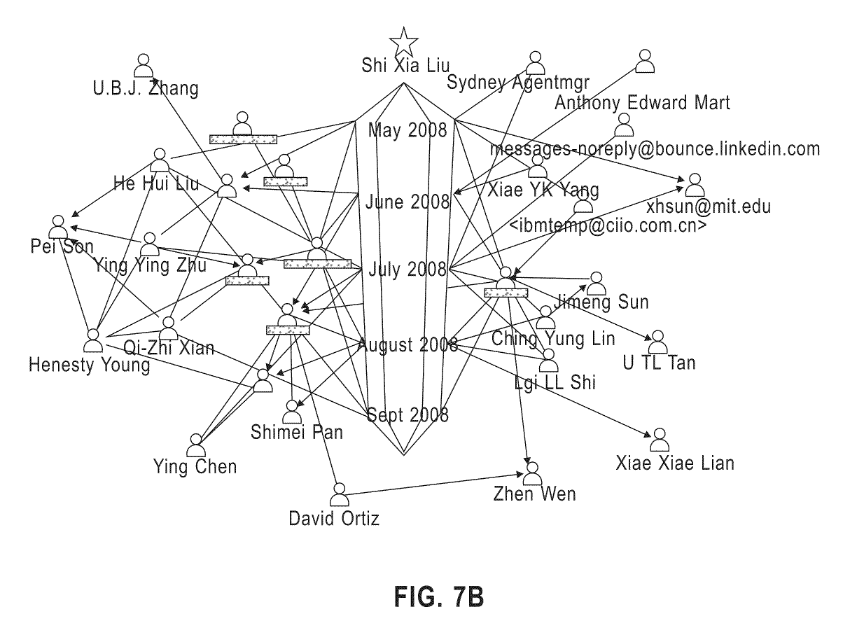

As an example, FIG. 7 illustrates a diagram of a network visualization representation according to an embodiment of the present invention, which can represent an email scenario, wherein the nodes/edge in FIG. 7 are filtered, only maintaining top 50 nodes and top 100 edges which communicate more with the analytic node. FIG. 7(a) is an original graph, and FIG. 7(b) is a graph with selected key nodes.

Edges in the topology can include a time-dependent edge and a time-independent edge. In this example, a time-dependent edge denotes an edge varying with time. For example, it is present in a static topology, while absent in another static topology. A time-independent edge is an edge not varying with time, for example present in all static topologies. As an embodiment of the present invention, a time-dependent edge connected to the analytic node is de-multiplexed based on a time value corresponding to the edge, so as to be connected to a particular part of the main information dimension graph corresponding to the time value. On the other hand, other non-analytic nodes and time-independent edges can retain their shapes and connection types as in a conventional visualization representation.

Optionally, this graph displays characteristics of edges in the network, i.e., characteristics of relationships between the neighboring nodes and the analytic nodes, through connection parts between the neighboring nodes and the main information dimension graph. For example, a narrow edge denotes a unidirectional edge, for example an edge between the analytic node and the node Li BJ Zhang in the graph, while a wide edge denotes a bidirectional edge, for example an edge between the analytic node and the node Nan CN Cao in the graph.

Embodiments of the present invention reveal a plurality of key characteristics of a dynamic ego network, including: grouping information surrounding an analytic node, which is equivalent to the community information the analytic node is participating in the entire time period in the social network scenario; a temporal connection information between the analytic node and one of its neighbors, with which information, temporal patterns within a social relationship in the social network scenario can be found; encoded time information of the analytic node, for example, sending/receiving frequency/volume. In a social network scenario, it can be a social activeness of a user represented by an analytic node, changing over time.

The major issue of the traditional visualization over the combined dynamic network lies in the deficiency of presenting the time-evolving network patterns. In previous visualization methods, time-dependent edges are drawn in parallel, and time information is only illustrated as a label, making it impossible to diagnose the sequential/causal relationships within the dynamic network. Embodiments of the present invention can present a plurality of static topologies in a single view, which can clearly represent change of the network with the main information dimension and is thus convenient for a visualization user to analyze the network state.

An overhead of applying the embodiments of the present invention, also known as additional visual complexity and computation, remains minor. Only the main information glyph presenting the selected analytic node set (normally 1˜2 nodes) will be shown as occupying more screen space, and the edge number is not increased from the combined dynamic network.

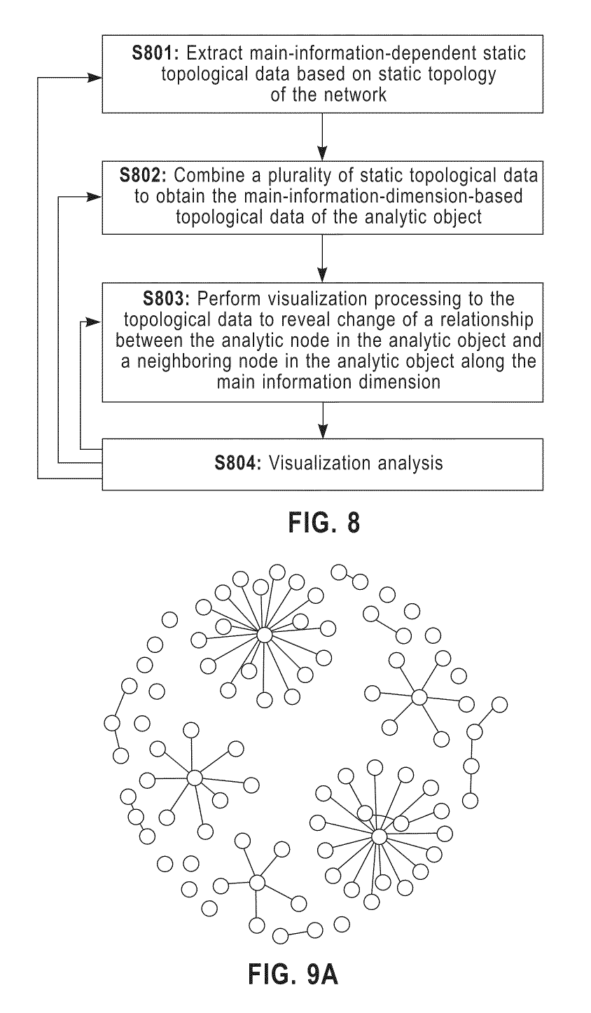

What is illustrated above is a network visualization representation method according to the present invention with reference to a simple network. Hereinafter, performing visualization processing to a complex network or improvement on the above topological representation will be illustrated with reference to FIG. 8.

FIG. 8 illustrates a flow chart of a network visualization processing method according to an embodiment of the present invention. At step S801, main-information-dependent static topological data are extracted based on static topology of a network regarding the main information.

At step S802, static topological data of a plurality of static topologies are combined to obtain main-information-dimension-based topological data of an analytic object.

At step S803, visualization processing is performed on main-information-dimension-based topological data of the analytic object, so as to reveal change of the analytic object along the main information dimension. This step can be similar to step S302 of FIG. 3.

At step S804, visualization analysis is performed to analyze and diagnose the network. For example, select/de-select instruction for a node from a user or a dimension scaling instruction from the user can be received.

Additionally, alternatively, a loop path can exist among the three steps. For example, a select/de-select instruction for a node from a user will trigger an online dynamic network data processing, and based on the select/de-select instruction, the data extracting step will determine an analytic node in an analytic object, which causes a new visualization of the network thereafter. For another example, after the dimension scaling instruction from the user is received, the combining step will determine the number of a plurality of static topologies for combining based on the dimension scaling instruction, and the visualization processing step will scale a display granularity of the main information dimension based on the dimension scaling instruction.

Hereinafter, exemplary depiction on an embodiment of the present invention will be made only with the example of time as main information. But it should be noted that the embodiment of the present invention is universal to all networks evolving along time dimension. For example, time evolution can be replaced as evolution along geographical locations or traveling path, evolution of role of a node, etc.

In this embodiment, step S801 can include analytic node-based dynamic network extraction. An analytic node is also called ego node. An analytic object is a network with an analytic object as the center, also called an ego-network.

As an embodiment of the present invention, a dynamic network is defined by an underlying graph of the network, which includes network nodes and edges connecting the nodes, while both the nodes and edges vary with time. A dynamic network D is represented by a time-evolving graph G(t), wherein t ∈ [0, T] denotes time, V(t) denotes a vertex set in the graph, while E(t) denotes an edge set in the graph.

This step is based on a user-defined analytic node set, and topological data are obtained through the network extracting step. An analytic node set is the focused node set within a network which receives the highest interest of the user. An analytic node set can include a single node or a plurality of nodes, and then the extracted network topological data are relevant to an analytic object whose center is the analytic node.

As mentioned above, step S801 is an extracting step. In this step, network extraction is performed on a static snapshot of the dynamic network at each specific time frame. Given the static network graph G(t) at time t with a vertex set V(t) and edge set E(t), an ego-network whose center is the node set Ω within N(t) is defined by an ego-graph G (Ω, t) with vertex set V(Ω, t) and edge set E(Ω, t), as illustrated in the following formula:

V(Ω, t)=Ω∪{v|v∈V(t)λ(∃u∈Ωᵥ(v, u) ∈ E(t)λ(u, v) ∈ E(t)}

E(Ω, t)={e=(v₁, v₂)|e∈E(t)λv₁∈V(Ω, t)λv₂∈V(Ω, t)},

Namely, a node set V(Ω, t) of the ego-network is composed of nodes having edges with the analytic nodes within given time t, also known as neighboring nodes, and an edge set E(Ω, t) of the ego-network is composed of edges between analytic nodes and between the analytic nodes and neighboring nodes within given time t. The above embodiment can present neighboring nodes having a “one-hop” relationship with analytic nodes, edges between analytic nodes, edges between analytic nodes and neighboring nodes, and edges between neighboring nodes. However, it is only an example, and in specific implementation, it can include one or more of the above, or select other nodes and edges to be displayed as required by analysis.

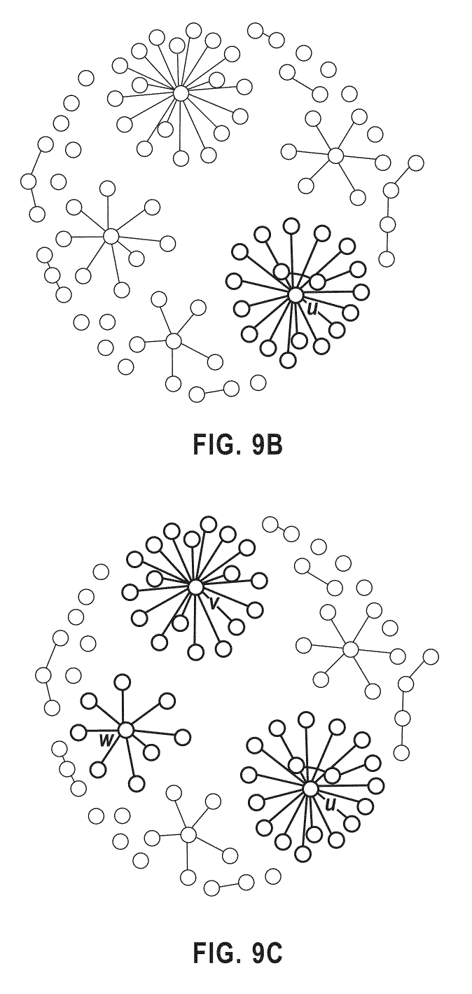

FIG. 9 illustrates a diagram of topological data extraction according to an embodiment of the present invention, wherein FIG. 9(a) is an entire network graph, FIG. 9(b) highlights an ego-network whose center is node u, and FIG. 9(c) highlights an ego-network whose center is a node set Ω={u, v, w}. After the extracting step, a series of static network can be obtained, which series of static networks have an underlying graph of G(Ω, t) at each specific time t.

As an embodiment of the present invention, at step S802, the dynamic ego-networks are combined based on a static ego-network at each time frame. Given a time-evolving static ego-network graph G(Ω, t), whose center is the node set Ω, wherein the node set of time t is denoted by V(Ω, t) and edge set is denoted by E(Ω, t), the combined dynamic ego-network D, represented by its underlying graph G(Ω), is computed by:

$$V ( Ω ) = {⋃}_{t ∈ [ 0 , T ]} V ( Ω , t )$$

$$E ( Ω ) = {E}_{I} ( Ω ) ⋃ {E}_{D} ( Ω ) ,$$

wherein,

$${E}_{I} ( Ω ) = \{ e = ( {v}_{1} , {v}_{2} ) \vert {v}_{1} ∉ Ω ⋀ {v}_{2} ∉ Ω ⋀ ( ∃ t , ( {v}_{1} , {v}_{2} , t ) ∈ E ( Ω , t ) ) \}$$

$${E}_{D} ( Ω ) = {⋃}_{t ∈ [ 0 , T ]} \{ e = ( {v}_{1} , {v}_{2} , t ) ∈ E ( Ω , t ) \vert {v}_{1} ∈ Ω ⋁ {v}_{2} ∈ Ω \}$$

Additionally, the edge set E(Ω) is composed of two subsets: E_{I}(Ω), which includes time-independent edges represented by e=(v1, v2); E_{D}(Ω), which includes a time-dependent edge presented by e=(v1, v2, t). A time-independent edge is independently determined by a source and a target node connected by the edge, and a plurality of time-dependent edges can exist simultaneously between a pair of nodes, wherein one of the time-dependent edges is for each specific time frame.

In the above embodiment, the dynamic network combination step maintains all edges incident to the node set Ω as time-dependent edges and aggregates other edges not incident to the node set Ω as time-independent edges.

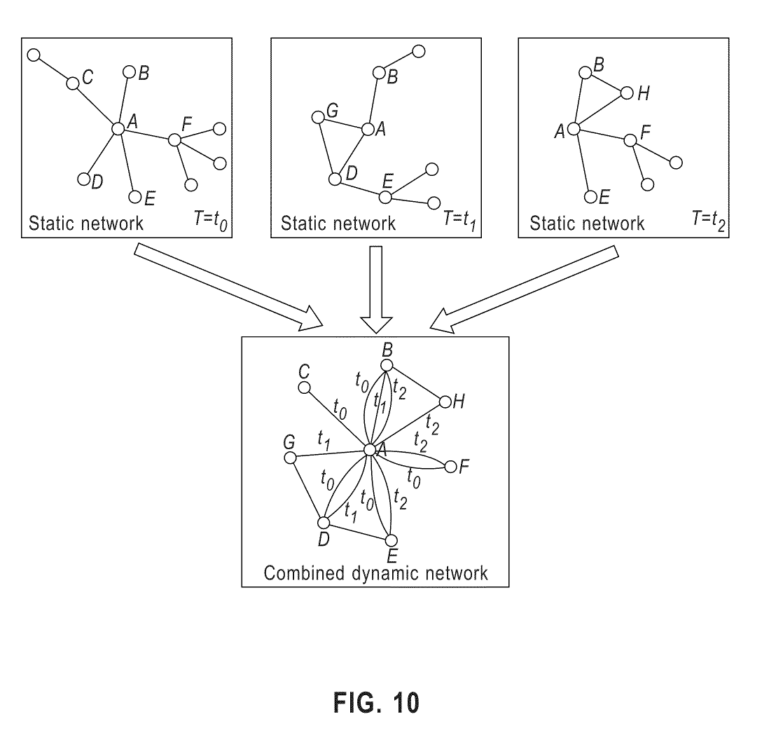

FIG. 10 illustrates a diagram of topological data combination according to an embodiment of the present invention, wherein the dynamic network includes three time frames t0, t1, and t2. The networks are combined based on the analytic node set Ω={A}. In the combined network, edges without labels indicate time-independent edges, for example the edge between the node B and the node H, while edges with labels indicate time-dependent edges, for example edges between the node A and the node B, wherein the labels notify exact time information attached to the edges. Additionally, different colors, widths, or linetypes can also be used to indicate edge information such as time-independent edges or time-dependent edges.

An extension for dynamic network combination is to introduce time dimension combination to time-dependent edges. Given a time dimension mapping from [0, T] to {S₁, S₂, . . . , Sₘ}, wherein Sᵢ [̅0̅, T], time-dependent edges of the combined dynamic networks are further reduced to:

$${⋃}_{i ∈ [ 1 , m ]} \{ e = ( {v}_{1} , {v}_{2} , {S}_{i} ) \vert ∃ t ∈ {S}_{i} , ( {v}_{1} , {v}_{2} , t ) ∈ E ( Ω , t ) ⋀ ( {v}_{1} ∈ Ω ⋁ {v}_{2} ∈ Ω ) \}$$

As an embodiment of the present invention, the combination step can determine neighboring nodes having a predetermined number of edges with the analytic nodes in a plurality of static topologies, for example, to maintain only neighboring nodes having edges exceeding a predetermined number with the analytic nodes.

Step S803 can include visualization composition and presentation. This step substantially creates visualization of dynamic networks and illustrates a combined dynamic network. This step is similar to the above step S302.

Optionally, layout of a visualization graph can be optimized so as to avoid graph overlap, which can also make the visualization graph much clearer so as to provide convenience for the user to analyze the network state. In embodiments of the present invention, because only a selected analytic node is fixed in the graph layout, a layout algorithm can be provided in a sufficient space to generate a visual aesthetic graph layout.

As an embodiment of the present invention, a force-directed algorithm can be referred to lay out a visualization graph of the analytic object. Based on the force-directed algorithm, an objective of laying out a graph is to minimize the graph energy of the final layout. A significant difference of the embodiments of the present invention over a standard force-directed algorithm lies in three aspects: 1) before being inputted to the layout algorithm, each node in the analytic node set is split into a plurality of sub-nodes based on time dimension values; 2) before implementing layout, positions of split sub-nodes are fixed, and the layout algorithm only counts energy of nodes not in the analytic node set; 3) adding a customized layout adjustment stage to avoid potential overlap with nodes in the analytic node set.

As an embodiment of the present invention, the layout algorithm works in three steps: graph preparation; graph layout calculation; and graph layout adjustment.

In the graph preparation step, given a combined dynamic network graph G(Ω) whose center is analytic node set Ω, with a total node set V(Ω) and a total edge set E(Ω); the generated graph for layout is computed as LG(Ω), with a node set LV(Ω) and edge set LE(Ω), according to the following formula:

LV(Ω)=(V(Ω)−Ω)∪ΦV(Ω),

LE(Ω)=EI(Ω)∪ΦE(ED(Ω)),

wherein,

Φ_{V}(Ω)={v^{(t)}|v∈Ωλt∈[0, T]},

Φ_{E}(E_{D}(Ω))={(v₁, v^{(t)})|v∈Ωλt∈[0, T]λ(v₁, v, t) ∈ E_{D}(Ω)}∪{(v^{(t)}, v₂)|v∈Ωλt∈[0, T]λ(v, v₂, t) ∈ E_{D}(Ω)}

In the above formula, v^{(t)} denotes a split sub-node of the analytic node v in a time frame t.

In a graph layout calculation step, graph layout is calculated over the LG(Ω) through a force-directed algorithm. Generally, the force-directed algorithm works by inserting spring embedders/stress-forces between nodes or by defining energy function for the graph. The final goal of the algorithm is to adjust the node positions to achieve the global minimization of the system energy. According to an embodiment of the present invention, improvement over these kinds of algorithms is to only consider the energy related to the non-analytic nodes (not in the analytic node set) and not to move the position of nodes in the analytic node set during the layout process.

For example, in the well-known Kamada-Kawai layout method, the energy function is defined by:

$$Γ = ( 1 - α ) {\sum }_{i = 1}^{n - 1} {\sum }_{j = i + 1}^{n} {{ω}_{ij} ( ‖ {X}_{i} - {X}_{j} ‖ - {d}_{ij} )}^{2} + α {\sum }_{i ∈ 1}^{n} {μ}_{i} {‖ {X}_{i} - {X}_{i}^{′} ‖}^{2}$$

Laying out the positions of the neighboring node graph includes laying out a position of the neighboring node graph according to the above formula. In this formula, the first item denotes the graph layout aesthetic energy, Xᵢ denotes the horizontal coordinate of the node vᵢ in the graph LG(Ω), Xⱼ denotes the transversal coordinate of the node vⱼ, dᵢⱼ denotes the optimal distance between node vᵢ and node vⱼ, wᵢⱼ denotes the modification coefficient; the second item denotes stable energy, Xᵢ′ denotes the stable point of node vᵢ, and α denotes a stable coefficient for balancing the first item and the second item.

As an embodiment of the present invention, the energy function can be set more accurately through the following formula:

$${ω}_{ij} = \{ \begin{matrix}0 & {v}_{i} ∈ Ω ⋀ {v}_{j} ∈ Ω \\ {d}_{ij}^{- 2} & Otherwise\end{matrix}$$

Where wᵢⱼ denotes a modification coefficient, dᵢⱼ denotes the optimal distance between node vᵢ and node vⱼ, and Ω denotes an analytic node set.

It should be noted that the above formula and selection of the modification coefficient are empirical values, which can be adaptively adjusted in practical implementation.

In the above embodiment, the energy introduced by the mutual interaction of nodes in the analytic node set is not considered in the system energy minimization.

In the step of graph layout adjustment, node positions have been adjusted to avoid overlapping. Substantially, the force-directed layout algorithm already resolves the node overlapping issue by imposing the optimal distance and/or spring forces between nodes. However, this is the case for graphs with regular-shape nodes, while in the graph layout according to embodiments of the present invention, the analytic nodes in the analytic node set are displayed by glyphs that occupy irregular screen space. In order to solve this problem, a post-layout adjustment is introduced into an embodiment of the present invention.

With a graph with a vertical glyph as an example, the x-axis coordinate of each non-analytical node is adjusted. Let vᵢ denote one of the non-central node, with position (xᵢ, yᵢ) after the layout. Assume vᵢ is placed between two vertical glyphs with x-axis coordinates of xₛ and xₜ, maximal width wₛ and wₜ. If there is no glyph in the left of vᵢ, then xₛ is set to the x-coordinate of left margin of the screen and wₛ set to 0. Similarly in the case where there is no glyph in the right of vᵢ, xₛ is set to the x-coordinate of right margin of the screen and wₜ set to 0. Then the x-axis coordinate of vᵢ is adjusted to:

$${x}_{i}^{*} = ( {x}_{s} + {w}_{s} / 2 ) + \frac{{x}_{i} - {x}_{s}}{{x}_{t} - {x}_{s}} \times ( {x}_{t} - {x}_{s} - {w}_{t} / 2 - {w}_{s} / 2 )$$

Through the above embodiment, the graph layout with horizontal glyphs can be adjusted accordingly. For other form of glyph, position adjustment can be performed with reference to the above method.

As an embodiment of the present invention, apart from the general-purpose interactions of network visualization analysis (such as dragging, highlighting and zooming), step S804 further includes several types of customized interactions for dynamic ego network visualization, for example analytic node select/de-select, main information dimension expand/collapse, and dimension scaling of main information dimension, etc. If the analytic task is entity-centric rather than topology-centric, then the visualization analysis step according to embodiments of the present invention will become more useful. Exemplary tasks include role analysis and spammer detection/validation.

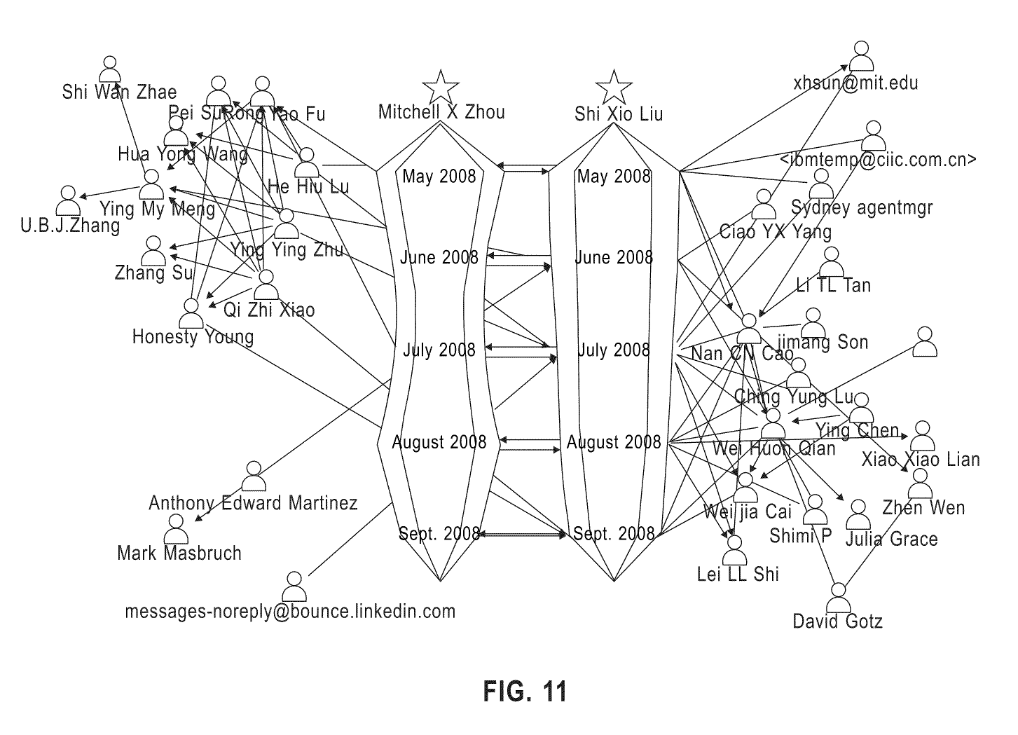

During the interaction between analytic node select/de-select, expansion of the circle in space and topology is implemented by selecting the nodes not in the analytic node set. FIG. 11 illustrates a diagram of an ego network having an ego node set including two nodes according to an embodiment of the present invention. The operation of analytic node select is to add neighbors of the newly selected analytic node and to connect them to edges of the graph. The analytic node de-select is an inverse operation of the select interaction.

During the interaction of main information dimension expand/collapse, for example, time dimension node expand/collapse, the expansion operation is to expand the graph at the time dimension. When the additional node is selected for expansion, it will be illustrated by glyph according to the graph type, in replacement of a regular-shape node.

With the increase of the range of the main information dimension such as the increase of time range, the dynamic network visualization processing method will suffer from visual clutter caused by a great number of edges. In order to solve this problem, a dimension scaling interaction, for example time dimension scaling, is introduced in an embodiment of the present invention, which is also called time dimension edge grouping. The user can select to group the time dimension edges by different scales, such as year/month/week/day/hour. For example, when the edges are grouped by year, all the time-dependent edges connecting the same pair of nodes and happening in the same year will run as one single edge after the operation, which allows the user to diagnose the temporal relationships in multiple levels of granularities.

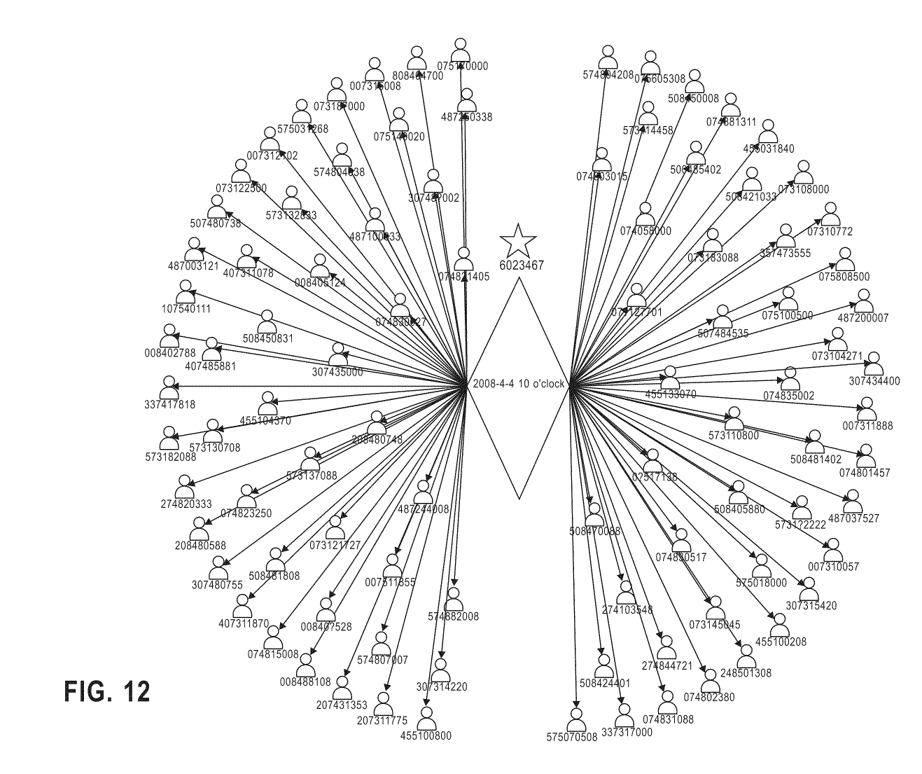

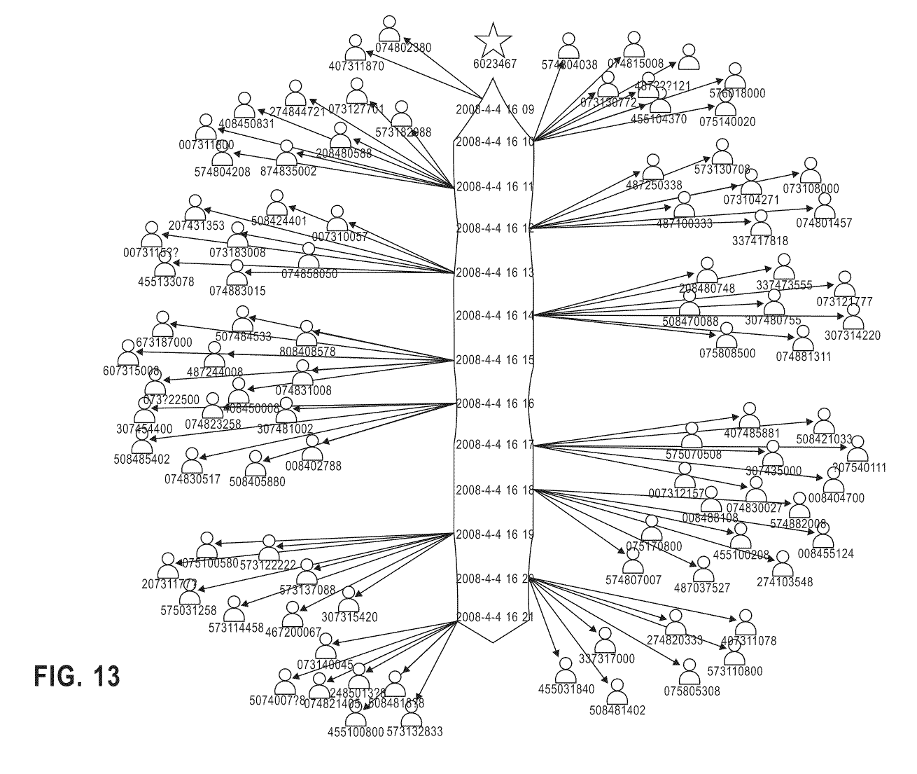

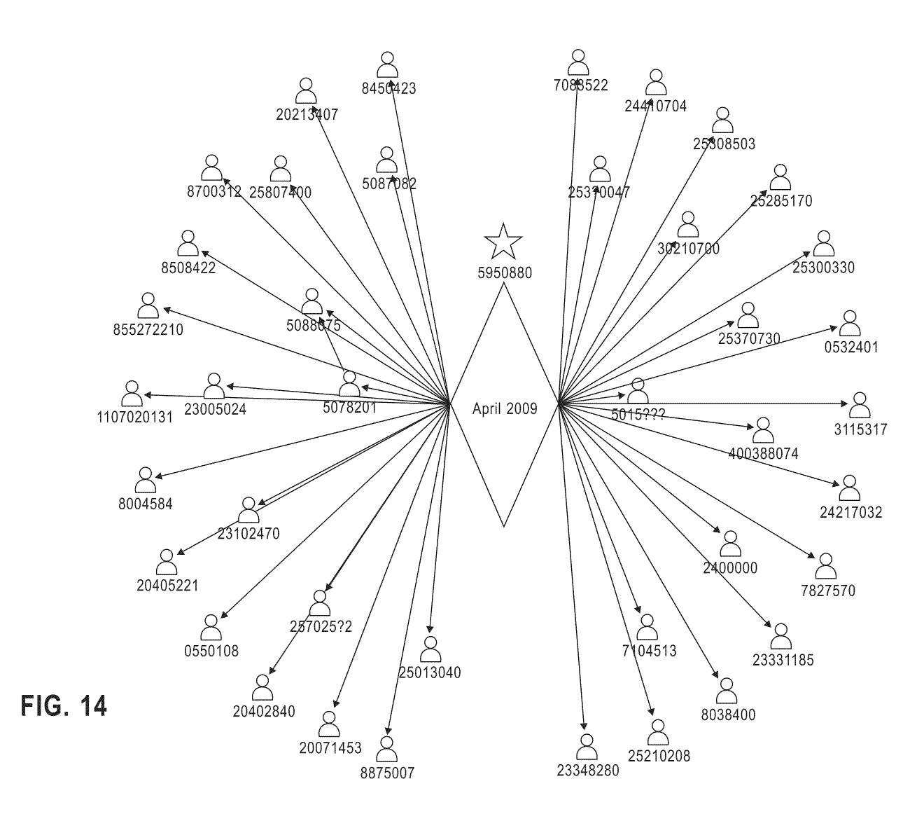

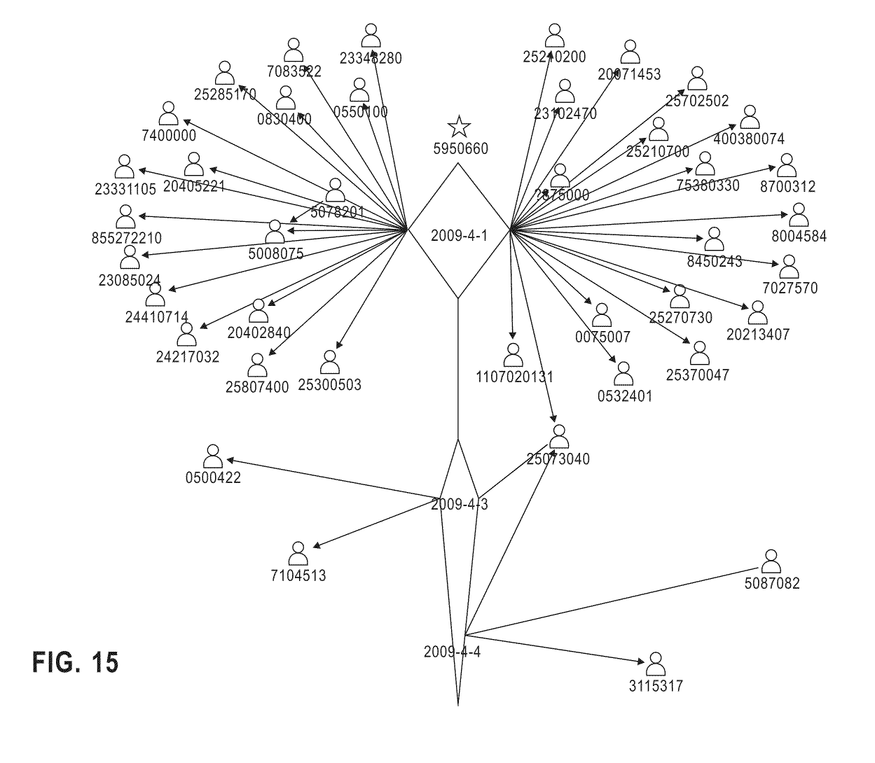

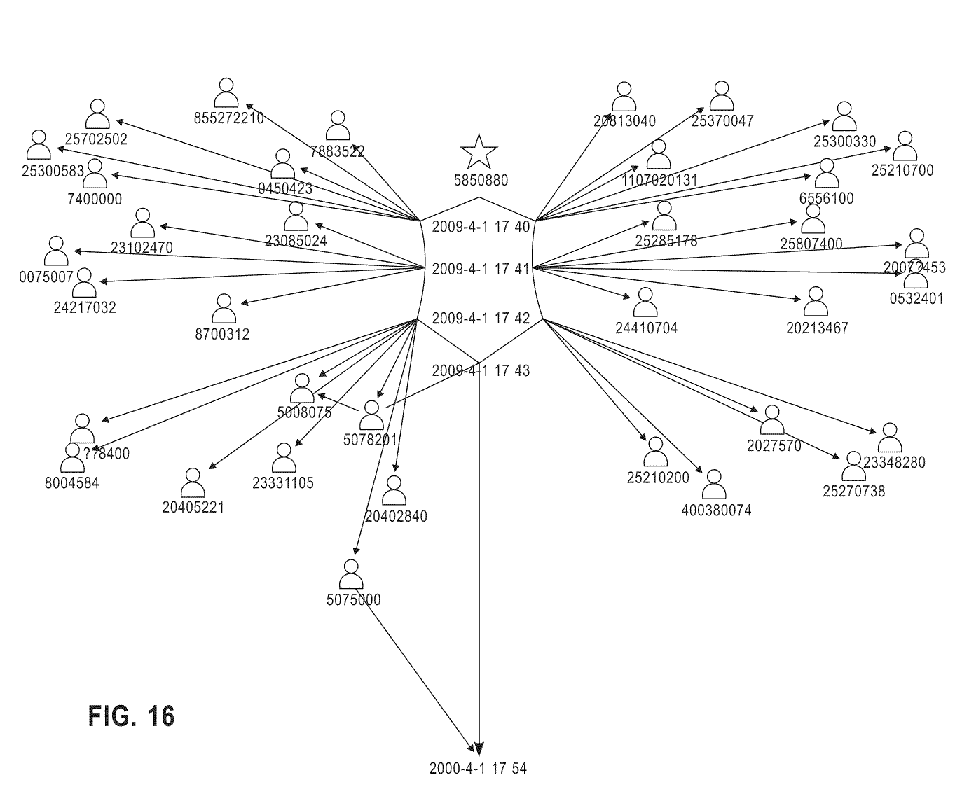

FIGS. 12-16 illustrate the evolving process of the above steps. FIG. 12 illustrates a dynamic ego network of an SMS spammer who sends out more than a hundred short messages within an hour; FIG. 13 illustrates the same ego network of SMS user after the edges are set to group by minutes; it can be found that the spammer tends to send messages with stable frequency; FIG. 14 illustrates a normal SMS user's ego network within a month; FIG. 15 illustrates the normal user's ego network after edges are grouped by day; and FIG. 16 illustrates the normal user's ego network after edges are grouped by minutes. Namely, time range is changed to the day of 2009 Apr. 1.

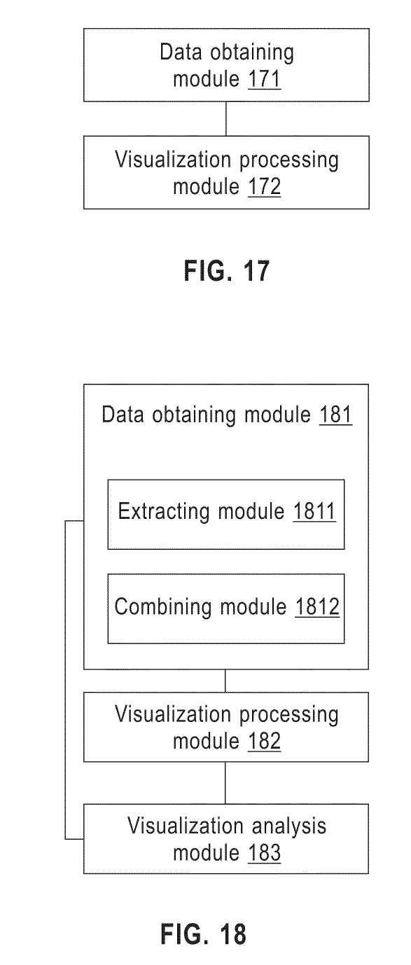

FIG. 17 illustrates a block diagram of a network visualization processing apparatus according to an embodiment of the present invention. The network visualization processing apparatus includes data obtaining module 171 for obtaining main-information-dimension-based topological data of an analytic object within a network; and visualization processing module 172 for performing visualization processing to the main-information-dimension-based topological data of the analytic object so as to reveal change of a relationship between an analytic node and a neighboring node in the analytic object along the main information dimension.

FIG. 18 illustrates a block diagram of a network visualization processing apparatus according to another embodiment of the present invention. Similar to the apparatus of FIG. 17, the network visualization processing apparatus of FIG. 18 includes data obtaining module 181 for obtaining main-information-dimension-based topological data of an analytic object within a network; and visualization processing module 182 for performing visualization processing to the main-information-dimension-based topological data of the analytic object so as to reveal change of the analytic object along the main information dimension.

In the network visualization processing apparatus of FIG. 18, the data obtaining module 181 includes extracting module 1811 for extracting main-information-dependent static topological data based on the main-information-dependent static topology of the network; and combining module 1812 for combining static topological data of a plurality of static topologies to obtain the main-information-dimension-based topological data of the analytic object.

As an embodiment of the present invention, the extracting module 1811 is further for extracting at least one piece of the following information: neighboring nodes of an analytic node in the analytic object, wherein the neighboring nodes include nodes having edges with the analytic node in the static topology; and edges between the analytic node and its neighboring nodes.

As an embodiment of the present invention, the combining module 1812 is further for determining a neighboring node having a specific number of edges with the analytic node in a plurality of static topologies.

In the network visualization processing apparatus of FIG. 18, the visualization processing module 182 is for displaying the analytic node in the analytic object as a main information dimension graph including information of the main information dimension, which is further for displaying the number of edges of the analytic node and its neighboring nodes through graphical settings of the main information dimension graph. The visualization processing module 182 can be further for connecting the neighboring nodes of the analytic node to the main information dimension graph, wherein the connection positions between the neighboring nodes and the main information dimension graph denote main information of the edges between the analytic nodes and its neighboring nodes, which can be further for displaying characteristics of the edges within the network through the connection parts connecting the neighboring nodes and the main information dimension graphs, ie., the characteristics of the relationship between the neighboring nodes and the analytic node. The visualization processing module 182 can be further for laying out the positions of the neighboring nodes based on a force-directed algorithm.

The network visualization processing apparatus of FIG. 18 includes a visualization analysis module 183 for receiving a dimension scaling instruction from a user.

The data obtaining module 181 is further for determining a length of the main information dimension based on a dimension scaling instruction from a user. The visualization processing module 182 is further for scaling the display granularities of the main information dimension based on the dimension scaling instruction.

As an embodiment of the present invention, main information can include time, space, node within an organization, role of the node, and any other information in which a user can be interested.

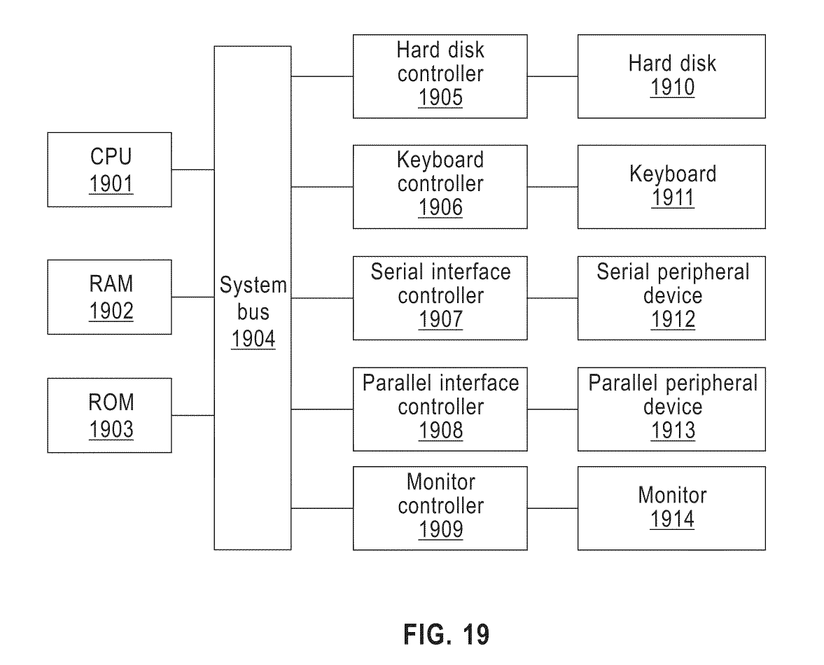

FIG. 19 illustrates a structural block diagram of a computer device capable of implementing the embodiments according to the present invention. The computer system as shown in FIG. 19 includes a CPU (Central Processing Unit) 1901, a RAM (Random Access Memory) 1902, a ROM (Read Only Memory) 1903, a system bus 1904, a hard disk controller 1905, a keyboard controller 1906, a serial interface controller 1907, a parallel interface controller 1908, a monitor controller 1909, a hard disk 1910, a keyboard 1911, a serial peripheral device 1912, a parallel peripheral device 1913 and a monitor 1914. Among these components, connected to the system bus 1904 are the CPU 1901, the RAM 1902, the ROM 1903, the hard disk controller 1905, the keyboard controller 1906, the serial interface controller 1907, the parallel interface controller 1908 and the monitor controller 1909. The hard disk 1910 is connected to the hard disk controller 1905; the keyboard 1911 is connected to the keyboard controller 1906; the serial peripheral device 1912 is connected to the serial interface controller 1907; the parallel peripheral device 1913 is connected to the parallel interface controller 1908; and the monitor 1914 is connected to the monitor controller 1909.

The structural block diagram in FIG. 19 is shown only for illustration purpose, and is not intended to limit the invention. In some cases, some devices can be added or reduced as required.

Further, the embodiments of the present invention can be implemented in software, hardware or the combination thereof. The hardware part can be implemented by a special logic; the software part can be stored in a memory and executed by a proper instruction execution system such as a microprocessor or a dedicated designed hardware. Those normally skilled in the art can understand that the above method and system can be implemented with a computer-executable instruction and/or in a processor control code, for example, such code is provided on a bearer medium such as a magnetic disk, CD, or DVD-ROM, or a programmable memory such as a read-only memory (firmware) or a data bearer such as an optical or electronic signal bearer. The system and its components in the present embodiment can be implemented by hardware circuitry of a programmable hardware device such as a very large scale integrated circuit or gate array, a semiconductor such as logical chip or transistor, or a field-programmable gate array, or a programmable logical device, or implemented by software executed by various kinds of processors, or implemented by combination of the above hardware circuitry and software.

The network visualization processing method and apparatus according to embodiments of the present invention facilitates temporal, spatial, and social compression to thereby reduce the network complexity. A new visual metaphor is introduced to represent time dimension information within a single network view.

Advantageous effects of the network visualization processing method and apparatus according to the embodiments of the present invention include: compared with the video approach splitting the network in time-dimension and presenting different networks in continuous time, the method and apparatus according to embodiments of the present invention aggregate the network scenario of the entire time period into a single view, so that the user needs not to navigate in the timeline to analyze the dynamic network; compared with the small multiple display dividing the view space spatially to show network of different time simultaneously, the method and apparatus according to embodiments of the present invention perform much better with the entire screen showing the single aggregated network, providing tens of times better resolution than the previous approach.

The network visualization processing method and apparatus according to the embodiments of the present invention actually show a subset of the dynamic network. However, this is compensated by the advanced user interaction, through which the user can navigate the entire network. Furthermore, the user can select to expand/aggregate the specific node/edge along the main information dimension to view more/less main information.

Through the above description of specific embodiments, it can be understood by those skilled in the art that the system, means and method as described above can be implemented by using computer executable instructions and/or being contained in processor control codes, for example, such codes are provided on an carrier medium such as a disk, CD or DVD-ROM, an programmable memory such as a read-only memory (firmware), or a data carrier such as a optical or electronic signal carrier. The means, server and its unit can be implemented by a hardware circuit of a super large-scale integrated circuit or gate array, a semiconductor such as a logic chip, transistor and so on, or a programmable hardware device such as a field programmable gate array, programmable logic device and so on, or by software executed by a variety of processors, or by a combination of above hardware circuit and software.

Although detailed description of the system and method for processing network visualization according to the invention has been made in combination with the above specific embodiments, the present invention is not limited thereto. Various variations, alternations and modifications to the invention can be made by those skilled in the art under teachings of the specification without departing from the scope and principle of the invention. It should be understood that all such variations, alternations and modifications still fall into the protection scope of the invention which is defined by the attached claims.

What is claimed is:

1. A network visualization processing method, comprising:
obtaining main-information-dimension-based topological data of an analytic object within a network; and
performing visualization processing to said main-information-dimension-based topological data of said analytic object so as to reveal change of a relationship between an analytic node in said analytic object and a neighboring node in said analytic object along a main information dimension.

2. The network visualization processing method according to claim 1, wherein said step of obtaining said main-information-dimension-based topological data of said analytic object within a network further comprises:
extracting main-information-dependent static topological data of said analytic object based on a static topology of said network; and
combining a plurality of the static topological data to obtain said main-information-dimension-based topological data of said analytic object.

3. The network visualization processing method according to claim 2, wherein said step of combining a plurality of the static topological data further comprises:
determining said neighboring node in said static topology having a predetermined relationship with said analytic node.

4. The network visualization processing method according to claim 1, wherein said step of performing visualization processing further comprises:
displaying said analytic node in said analytic object as a main information dimension graph.

5. The network visualization processing method according to claim 4, wherein said step of performing said visualization processing further comprises:
presenting a neighboring node of said analytic node as a neighboring node graph; and
connecting said neighboring node graph to said main information dimension graph, wherein a position with regard to said main information dimension graph of a connection part between said neighboring node graph and said main information dimension graph represents said main information regarding said relationship between said analytic node and its neighboring node.

6. The network visualization processing method according to claim 5, wherein said step of performing visualization processing further comprises:
laying out a position of said neighboring node graph based on a force directed algorithm.

7. The network visualization processing method according to claim 4, wherein said step of performing visualization processing further comprises:
displaying information regarding the relationship between the analytic node and its neighboring node by graphical settings of the main information dimension graph.

8. The network visualization processing method according to claim 5, wherein said step of performing visualization processing further comprises:
displaying characteristics of the relationship between said analytic node and its neighboring node through a connection part connecting said neighboring node graph and said main information dimension graph.

9. The network visualization processing method according to claim 1, further comprising:
receiving a dimension scaling instruction from a user;
determining a length of said main information dimension based on said dimension scaling instruction; and
scaling display granularities of said main information dimension based on said dimension scaling instruction.

10. A network visualization processing apparatus, comprising:
a data obtaining module, wherein said data obtaining module is configured to obtain main-information-dimension-based topological data of an analytic object within a network; and
a visualization processing module, where said visualization processing module is configured to perform visualization processing to said main-information-dimension-based topological data of said analytic object so as to reveal change of a relationship between an analytic node in the analytic object and a neighboring node in said analytic object along a main information dimension.

11. The network visualization processing apparatus according to claim 10, wherein said data obtaining module further comprises:
an extracting module, configured to extract main-information-dependent static topological data of said analytic object based on a static topology of said network; and
a combining module, configured to combine a plurality of the static topological data to obtain main-information-dimension-based topological data of said analytic object.

12. The network visualization processing apparatus according to claim 11, wherein said combining module determines said neighboring node in said static topology having a predetermined relationship with said analytic node.

13. The network visualization processing apparatus according to claim 10, wherein said visualization processing module displays an analytic node in said analytic object as main information dimension graph.

14. The network visualization processing apparatus according to claim 13, wherein said visualization processing module is further configured to:
present said neighboring node of said analytic node as a neighboring node graph; and
connect said neighboring node graph to said main information dimension graph;
wherein a position with regard to said main information dimension graph of a connection part between said neighboring node graph and said main information dimension graph represents said main information regarding the relationship between said analytic node and its neighboring node.

15. The network visualization processing apparatus according to claim 14, wherein said visualization processing module is further configured to lay out a position of said neighboring node graph based on a force-directed algorithm.

16. The network visualization processing apparatus according to claim 13, wherein said visualization processing module displays information regarding a relationship between said analytic node and its neighboring node through graphical settings of said main information dimension graph.

17. The network visualization processing apparatus according to claim 14, wherein said visualization processing module displays characteristics of said relationship between said analytic node and its neighboring node through a connection part connecting said neighboring node graph and said main information dimension graph.

18. The network visualization processing apparatus according to claim 10, further comprising;
a visualization analysis module, configured to receive a dimension scaling instruction from the user;
a measuring module that determines a length of the main information dimension based on said dimension scaling instruction; and
a scaling module configured to scale display granularities of said main information dimension based on said dimension scaling instruction.

19. A computer readable article of manufacture tangibly embodying computer readable instructions which, when executed, cause a computer to carry out the steps of a method according to claim 1.
